(19) United States
(12) Patent Application Publication
(10) Pub. No.: US 2026/0318975 A1
(43) Pub. Date: Oct. 15, 2026

(54) TIME-DOMAIN DIAGNOSIS METHOD AND APPARATUS FOR DEFECT OF POWER CABLE BASED ON CROSS-BONDING BOX STRUCTURE

(71) Applicant: TSINGHUA UNIVERSITY, Beijing (CN)

(72) Inventors: Bo ZHANG, Beijing (CN); Yaqiang DENG, Beijing (CN); Chaoran LI, Beijing (CN); Jinliang HE, Beijing (CN); Jun HU, Beijing (CN)

(21) Appl. No.: 19/698,905

(22) Filed: Jun. 5, 2026

Related U.S. Application Data
(63) Continuation of application No. PCT/CN2024/087490, filed on Apr. 12, 2024.

(30) Foreign Application Priority Data
Apr. 10, 2024 (CN) 202410426699.1

(51) Int. Cl. G01R 31/11; G01R 31/08

(52) U.S. Cl. CPC G01R 31/11; G01R 31/085

(57) ABSTRACT

The present disclosure relates to the field of high-voltage technologies, and in particular, to a time-domain diagnosis method and apparatus for a defect of a power cable based on a cross-bonding box structure. The method includes: injecting a broadband signal through a wiring terminal of a cross-bonding box for cross-connection of three-phase shielding layers, to collect an initial voltage time-domain waveform of a to-be-measured three-phase cable in a steady state generated based on the broadband signal; preprocessing the initial voltage time-domain waveforms at the same end, to obtain preprocessed voltage time-domain waveforms at a left end and a right end of the cross-bonding box; and diagnosing, based on the voltage time-domain waveforms at the left end and the right end, a defect existing in an outer sheath and main insulation of the to-be-measured three-phase cable, to obtain a final time-domain diagnosis result for the defect of the to-be-measured three-phase cable.

### CROSS-REFERENCE TO RELATED APPLICATIONS

This application is a continuation of International Patent Application No. PCT/CN2024/087490 filed on Apr. 12, 2024, which claims the priority to Chinese Patent Application No. 202410426699.1, filed by Tsinghua University on Apr. 10, 2024, entitled “TIME-DOMAIN DIAGNOSIS METHOD AND APPARATUS FOR DEFECT OF POWER CABLE BASED ON CROSS-BONDING BOX STRUCTURE”.

### FIELD

The present disclosure relates to the field of high-voltage technologies, and in particular, to a time-domain diagnosis method and apparatus for a defect of a power cable based on a cross-bonding box structure.

### BACKGROUND

A power cable is widely used in various industries such as power systems, urban rail transit, petrochemical engineering, and metallurgy, and is one of the key devices for power transmission and distribution. A cross-bonding system is a common design in a three-phase power cable, aiming to balance capacitance between phases, reduce interphase interference, and improve transmission capacity and stability of the power cable. However, since the power cable is buried underground for a long time, and is affected by various environmental factors such as temperature, humidity, and chemical corrosion, as well as a defect existing in its manufacturing process, various faults may occur during operation of the power cable. These faults may disrupt a balanced state of the cross-bonding system, leading to a change in a capacitance value of a faulty phase, and seriously affecting normal operation of the power cables. In addition, these faults may even cause power-supply interruptions, bringing great inconvenience to people's production and daily life.

In the related art, commonly used fault positioning methods include a bridge method, a pulse reflection method, and the like. The bridge method mainly utilizes a linear relationship between a length of a faulty power cable and its resistance, forming a bridge between resistance of core wires of power cables at two sides of a fault point and proportional resistance. In the pulse reflection method, a pulse signal is transmitted to the power cable. Based on a principle that electromagnetic wave reflection occurs when the pulse signal encounters a wave impedance mismatch point during its propagation in a power cable line, by analyzing a characteristic of a reflected signal, it can be determined whether a fault exists in the power cable, and a fault position may be determined.

However, in the related art, a detection signal is injected into a to-be-measured power cable system, which causes disconnection of the exposed core wires of the cable in the power cable system, thereby damaging a complete topological structure of the power cable system, making it difficult to achieve online monitoring. In addition, demand for an on-site device increases, and complexity and cost of a routing inspection are relatively high, making it unsuitable for daily diagnosis of the power cable system, with low practicality. An improvement is urgently required.

### SUMMARY

The present disclosure provides a time-domain diagnosis method and apparatus for a defect of a power cable based on a cross-bonding box structure, to solve technical problems in the related art, such as disconnection of exposed core wires of a cable in a power cable system, damage to a complete topological structure of the power cable system, difficulty in achieving online monitoring, increased demand for an on-site device, relatively high complexity and cost of a routing inspection, and low practicality.

An embodiment of a first aspect of the present disclosure provides a time-domain diagnosis method for a defect of a power cable based on a cross-bonding box structure. The method includes: injecting a broadband signal through a wiring terminal of a cross-bonding box for cross-connection of three-phase shielding layers, to collect an initial voltage time-domain waveform of a to-be-measured three-phase cable in a steady state generated based on the broadband signal; preprocessing the initial voltage time-domain waveforms at the same end to obtain preprocessed voltage time-domain waveforms at a left end and a right end of the cross-bonding box; and diagnosing, based on the voltage time-domain waveforms at the left end and the right end, the defect existing in an outer sheath and main insulation of the to-be-measured three-phase cable, to obtain a final time-domain diagnosis result for the defect of the to-be-measured three-phase cable.

Optionally, in an embodiment of the present disclosure, the preprocessing the initial voltage time-domain waveforms at the same end, to obtain the preprocessed voltage time-domain waveforms at the left end and the right end of the cross-bonding box includes: performing a discrete wavelet transform on the initial voltage time-domain waveforms, and selecting a hard threshold method to filter the initial voltage time-domain waveforms after the discrete wavelet transform to obtain the voltage time-domain waveforms.

Optionally, in an embodiment of the present disclosure, the hard threshold method is:

$${k}_{δ} = \{ \begin{matrix}{ψ}_{a , b} ( t ) , if \vert {ψ}_{a , b} ( t ) \vert > δ \\ 0\end{matrix} ,$$

in which k_{δ} is a wavelet transform coefficient processed by the hard threshold method, ψ_{a,b}(t) is a wavelet transform coefficient, and δ is a set hard threshold.

An expression of the hard threshold is:

$$δ = \frac{m}{0.6745} \cdot \sqrt{2 log n} ,$$

in which m is a median value of a signal decomposition layer, and n is a length of the signal decomposition layer.

Optionally, in an embodiment of the present disclosure, the diagnosing, based on the voltage time-domain waveforms at the left end and the right end, the defects existing in the outer sheath and the main insulation of the to-be-measured three-phase cable, to obtain the final time-domain diagnosis result for the defect of the to-be-measured three-phase cable includes: determining a phase where the defect is located based on the voltage time-domain waveforms; and determining a position where the defect is located and a direction of the defect based on the voltage time-domain waveforms.

Optionally, in an embodiment of the present disclosure, an absolute value of the position where the defect is located is:

$${L}_{f}^{kl} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

An embodiment of a second aspect of the present disclosure provides a time-domain diagnosis apparatus for a defect of a power cable based on a cross-bonding box structure. The apparatus includes: a collection module configured to inject a broadband signal through a wiring terminal of a cross-bonding box for cross-connection of three-phase shielding layers, to collect an initial voltage time-domain waveform of a to-be-measured three-phase cable in a steady state generated based on the broadband signal; a preprocessing module configured to preprocess the initial voltage time-domain waveforms at the same end, to obtain preprocessed voltage time-domain waveforms at a left end and a right end of the cross-bonding box; and a diagnosis module configured to diagnose, based on the voltage time-domain waveforms at the left end and the right end, the defect existing in an outer sheath and main insulation of the to-be-measured three-phase cable, to obtain a final time-domain diagnosis result for the defect of the to-be-measured three-phase cable.

Optionally, in an embodiment of the present disclosure, the preprocessing module includes: a generation unit configured to perform a discrete wavelet transform on the initial voltage time-domain waveforms, and select a hard threshold method to filter the initial voltage time-domain waveforms after the discrete wavelet transform to obtain the voltage time-domain waveforms.

Optionally, in an embodiment of the present disclosure, the hard threshold method is:

$${k}_{δ} = \{ \begin{matrix}{ψ}_{a , b} ( t ) , if \vert {ψ}_{a , b} ( t ) \vert > δ \\ 0\end{matrix} ,$$

in which k_{δ} is a wavelet transform coefficient processed by the hard threshold method, ψ_{a,b}(t) is a wavelet transform coefficient, and δ is a set hard threshold.

An expression of the hard threshold is:

$$δ = \frac{m}{0.6745} \cdot \sqrt{2 log n} ,$$

in which m is a median value of a signal decomposition layer, and n is a length of the signal decomposition layer.

Optionally, in an embodiment of the present disclosure, the diagnosis module includes: a first determination unit configured to determine a phase where the defect is located based on the voltage time-domain waveforms; and a second determination unit configured to determine a position where the defect is located and a direction of the defect based on the voltage time-domain waveforms.

Optionally, in an embodiment of the present disclosure, an absolute value of the position where the defect is located is:

$${L}_{f}^{kl} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

An embodiment of a third aspect of the present disclosure provides an electronic device. The electronic device includes: a memory; a processor; and a computer program stored on the memory and executable on the processor. The processor executes the program to implement the time-domain diagnosis method for the defect of the power cable based on the cross-bonding box structure as described in the above embodiments.

An embodiment of a fourth aspect of the present disclosure provides a computer-readable storage medium. The computer-readable storage medium has a computer program stored thereon. The program, when executed by a processor, is configured to implement the time-domain diagnosis method for the defect of the power cable based on the cross-bonding box structure as described above.

An embodiment of a fifth aspect of the present disclosure provides a computer program product. The computer program product includes a computer program. The computer program, when executed, is configured to implement the time-domain diagnosis method for the defect of the power cable based on the cross-bonding box structure as described above.

The present disclosure may inject the broadband signal through the wiring terminal of the cross-bonding box for cross-connection of the three-phase shielding layers, and diagnose, based on the voltage time-domain waveforms in the steady state generated based on the broadband signal, the time-domain diagnosis result of the defect existing in the outer sheath and the main insulation of the three-phase cable, which realizes simultaneous diagnosis of potential defects in the outer sheath and the main insulation of the three-phase cable and provides diagnostic positioning without disconnecting an electrical connection of a three-phase cable system, thereby realizing evaluation of a health state of the three-phase cable system, reducing the demand and cost of the on-site device, improving the practicality, and further making the online monitoring possible. Therefore, the technical problems in the related art, such as the disconnection of the exposed core wires of the cable in the power cable system, the damage to the complete topological structure of the power cable system, the difficulty in achieving the online monitoring, the increased demand for the on-site device, the relatively high complexity and cost of the routing inspection, and the low practicality, are solved.

Additional aspects and advantages of the present disclosure will be provided in part in the following description, or will become apparent in part from the following description, or can be learned from practicing of the present disclosure.

### BRIEF DESCRIPTION OF THE DRAWINGS

The above and/or additional aspects and advantages of the present disclosure will become apparent and readily appreciated from the following description of the embodiments in conjunction with the accompanying drawings, in which:

FIG. 1 is a schematic structural diagram of a constructed preset circuit provided according to an embodiment of the present disclosure;

FIG. 2 is a flowchart of a time-domain diagnosis method for a defect of a power cable based on a cross-bonding box structure provided according to an embodiment of the present disclosure;

FIG. 3 is a schematic block diagram of a working principle of a time-domain diagnosis method for a defect of a power cable based on a cross-bonding box structure provided according to an embodiment of the present disclosure;

FIG. 4 is a schematic block diagram of a time-domain diagnosis apparatus for a defect of a power cable based on a cross-bonding box structure provided according to an embodiment of the present disclosure; and

FIG. 5 is a schematic structural diagram of an electronic device provided according to an embodiment of the present disclosure.

201—waveform generation apparatus, 202—signal collection apparatus, 203—T-shaped connector, 204—signal connection cable, 2041—first cable segment, 2042—second cable segment, 205—in-service to-be-measured three-phase cable that does not undergo a disconnection treatment, 206—cross-bonding boxes at adjacent segments; 10—time-domain diagnosis apparatus for a defect of a power cable based on a cross-bonding box structure; 100—collection module, 200—preprocessing module, 300—diagnosis module; 501—memory, 502—processor, 503—communication interface.

### DETAILED DESCRIPTION

The embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limiting, the present disclosure.

A time-domain diagnosis method and apparatus for a defect of a power cable based on a cross-bonding box structure according to the embodiments of the present disclosure will be described below with reference to the accompanying drawings. Aiming at problems mentioned in the above background art, such as disconnection of exposed core wires of a cable in a power cable system, damage to a complete topological structure of the power cable system, difficulty in achieving online monitoring, increased demand for an on-site device, relatively high complexity and cost of a routing inspection, and low practicality, the present disclosure provides a time-domain diagnosis method for a defect of a power cable based on a cross-bonding box structure. In this method, a broadband signal may be injected through a wiring terminal of a cross-bonding box for cross-connection of three-phase shielding layers, and a time-domain diagnosis result of the defect existing in an outer sheath and main insulation of a three-phase cable may be diagnosed based on voltage time-domain waveforms in a steady state generated based on the broadband signal, which realizes simultaneous diagnosis of potential defects in the outer sheath and the main insulation of the three-phase cable and provides diagnostic positioning without disconnecting an electrical connection of a three-phase cable system, thereby realizing evaluation of a health state of the three-phase cable system, reducing the demand and cost of the on-site device, improving the practicality, and further making the online monitoring possible. Therefore, the technical problems in the related art, such as the disconnection of the exposed core wires of the cable in the power cable system, the damage to the complete topological structure of the power cable system, the difficulty in achieving the online monitoring, the increased demand for the on-site device, the relatively high complexity and cost of the routing inspection, and the low practicality, are solved.

Before the time-domain diagnosis method for the defect of the power cable based on the cross-bonding box structure provided according to the embodiments of the present disclosure is explained, an example of a constructed preset circuit involved in the embodiments of the present disclosure will be described first.

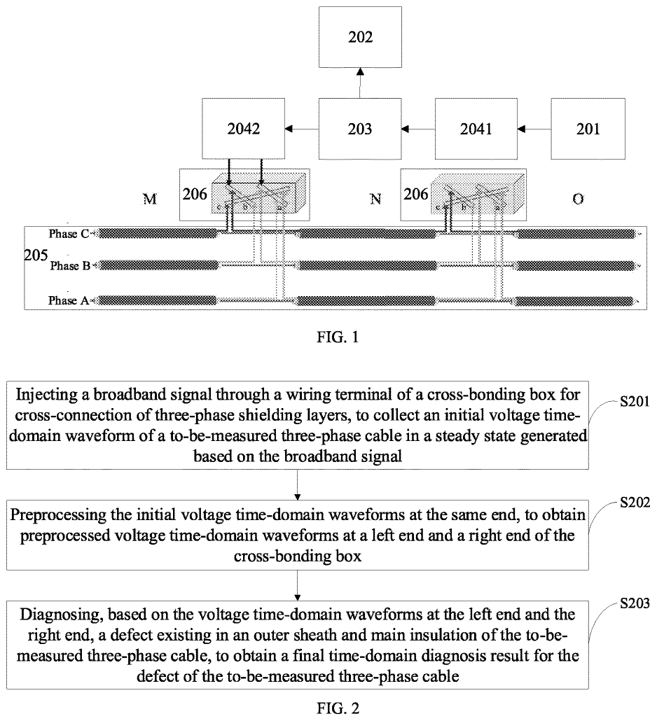

Specifically, FIG. 1 is a schematic structural diagram of a constructed preset circuit provided according to an embodiment of the present disclosure.

As shown in FIG. 1, 201 refers to a waveform generation apparatus, 202 refers to a signal collection apparatus, 203 refers to a T-shaped connector, 204 refers to a signal connection cable, 205 refers to an in-service to-be-measured three-phase cable that does not undergo a disconnection treatment, and 206 refers to cross-bonding boxes at adjacent segments.

In an embodiment, the waveform generation apparatus 201 may be a waveform generator that achieves impedance matching between internal resistance and the signal connection cable.

The signal collection apparatus 202 may select input resistance as large as possible to make it approximate an open-circuit state.

The signal connection cable 204 may include a first cable segment 2041 and a second cable segment 2042.

In addition, in the embodiment of the present disclosure, two adjacent cross-bonding boxes 206 may each be used to collect an initial voltage time-domain waveform generated by a to-be-measured three-phase cable 205 in a steady state.

Specifically, FIG. 2 is a flowchart of a time-domain diagnosis method for a defect of a power cable based on a cross-bonding box structure provided according to an embodiment of the present disclosure.

As shown in FIG. 2, the time-domain diagnosis method for the defect of the power cable based on the cross-bonding box structure includes the following steps.

In step S201, a broadband signal is injected through a wiring terminal of a cross-bonding box 206 for cross-connection of three-phase shielding layers, to collect an initial voltage time-domain waveform of a to-be-measured three-phase cable 205 in a steady state generated based on the broadband signal.

It can be understood that the to-be-measured three-phase cable 205 may be a three-phase cable that does not undergo a disconnection treatment, which may be an in-service to-be-measured three-phase cable 205 or a non-in-service to-be-measured three-phase cable 205. The present disclosure does not specifically limit this.

During actual implementation, in the embodiment of the present disclosure, by constructing the preset circuit, the broadband signal may be injected through the wiring terminal of the cross-bonding box 206 for cross-connection of the three-phase shielding layers, and then the initial voltage time-domain waveform generated by the to-be-measured three-phase cable 205 in the steady state may be collected.

In some embodiments of the present disclosure, as an example, potential defects of M, N, and O segments of the to-be-measured three-phase cable 205 are identified. The constructed preset circuit may be as shown in FIG. 1, and the process may be as follows.

First, a preset circuit is constructed, and an inspection is performed. That is, in the embodiments of the present disclosure, the preset circuit may be constructed in a manner shown in FIG. 1, and it is inspected whether a connection is electrically reliable after the preset circuit is constructed.

Then, a signal is outputted and collected. That is, in the embodiment of the present disclosure, the waveform generator may output a broadband signal with a certain repetition frequency, and the signal collection apparatus 202 may collect a port signal U0.

Next, an initial voltage time-domain waveform generated by an M-N segment of the to-be-measured three-phase cable 205 in a steady state is collected. In the embodiment of the present disclosure, an injection pole at an end of the second cable segment 2042 may be connected to a/a/b of the M-N segment of the cross-bonding box 206, and a return pole at the end of the second cable segment 2042 may be connected to c/b/c of the M-N segment of the cross-bonding box 206. Previous settings of the waveform generator and the signal collection apparatus 202 are maintained, port signals U1, U2, and U3 within a single cycle in the steady state under such a case are collected.

In addition, in the embodiment of the present disclosure, an initial voltage time-domain waveform generated by an N-O segment of the to-be-measured three-phase cable 205 in a steady state may also be collected. In the embodiment of the present disclosure, the injection pole at the end of the second cable segment 2042 may be connected to a/a/b of the N-O segment of the cross-bonding box 206, and the return pole at the end of the second cable segment 2042 may be connected to c/b/c of the N-O segment of the cross-bonding box 206. Previous settings of the waveform generator and the signal collection apparatus 202 are maintained, port signals U4, U5, and U6 within a single cycle in the steady state under such a case are collected.

In step S202, the initial voltage time-domain waveforms at the same end is preprocessed, to obtain preprocessed voltage time-domain waveforms at a left end and a right end of the cross-bonding box 206.

It can be understood that the initial voltage time-domain waveforms may contain noise and the like. In the embodiment of the present disclosure, the initial voltage time-domain waveforms may be preprocessed to perform noise reduction and the like.

As a possible implementation manner, in the embodiment of the present disclosure, the initial voltage time-domain waveforms at the same end may be preprocessed, to obtain the preprocessed voltage time-domain waveforms at the left end and the right end of the cross-bonding box 206.

Optionally, in an embodiment of the present disclosure, the preprocessing the initial voltage time-domain waveforms at the same end, to obtain the preprocessed voltage time-domain waveforms at the left end and the right end of the cross-bonding box 206 includes: performing a discrete wavelet transform on the initial voltage time-domain waveforms, and selecting a hard threshold method to filter the initial voltage time-domain waveforms after the discrete wavelet transform to obtain the voltage time-domain waveforms. The hard threshold method is:

$${k}_{δ} = \{ \begin{matrix}{ψ}_{a , b} ( t ) , if \vert {ψ}_{a , b} ( t ) \vert > δ \\ 0\end{matrix} ,$$

in which k_{δ} is a wavelet transform coefficient processed by the hard threshold method, ψ_{a,b}(t) is a wavelet transform coefficient, and δ is a set hard threshold.

An expression of the hard threshold is:

$$δ = \frac{m}{0.6745} \cdot \sqrt{2 log n} ,$$

in which m is a median value of a signal decomposition layer, and n is a length of the signal decomposition layer.

In some embodiments of the present disclosure, based on U1 to U6 obtained in step S201, the discrete wavelet transform may be performed, and the hard threshold method may be selected to filter the collected initial voltage time-domain waveforms. The wavelet transform coefficient ψ_{a,b}(t) is expressed as:

$${ψ}_{a , b} ( t ) = \frac{1}{\sqrt{{2}^{a}}} ψ ( \frac{t - b}{{2}^{a}} ) ,$$

in which ψ is a wavelet basis function.

Further, in the embodiment of the present disclosure, a 5-layer decomposition coefficient and the hard threshold method may be selected to filter out the noise. The hard threshold method is:

$${k}_{δ} = \{ \begin{matrix}{ψ}_{a , b} ( t ) , if \vert {ψ}_{a , b} ( t ) \vert > δ \\ 0\end{matrix} ,$$

in which k_{δ} is a wavelet transform coefficient processed by the hard threshold method, ψ_{a,b}(t) is a wavelet transform coefficient, and δ is a set hard threshold.

The expression of the hard threshold is:

$$δ = \frac{m}{0.6745} \cdot \sqrt{2 log n} ,$$

in which m is a median value of a signal decomposition layer, and n is a length of the signal decomposition layer.

Further, in the embodiment of the present disclosure, an inverse wavelet transform is performed on the filtered result to obtain the voltage time-domain waveforms after the noise filtration.

In step S203, a defect existing in an outer sheath and main insulation of the to-be-measured three-phase cable 205 is diagnosed based on the voltage time-domain waveforms at the left end and the right end, to obtain a final time-domain diagnosis result for the defect of the to-be-measured three-phase cable 205.

It can be understood that the outer sheath and the main insulation are important parts of the to-be-measured three-phase cable 205, and their integrity is crucial to normal operation and safety of the to-be-measured three-phase cable 205.

The outer sheath is an outermost protection layer of the to-be-measured three-phase cable 205, which mainly prevents the to-be-measured three-phase cable 205 from being affected by an external environment, such as moisture, chemical substances, and mechanical damage. If the outer sheath has a defect, such as damage, aging, and cracking, external moisture and chemical substances may infiltrate an interior of the cable, thereby damaging a main insulation layer and affecting the normal operation.

The main insulation layer is an isolation layer between an internal conductor of the to-be-measured three-phase cable 205 and the external environment, and mainly bears a voltage of the to-be-measured three-phase cable 205 during operation, preventing the occurrence of current leakage and electric shock accidents. If the main insulation layer has a defect, such as bubbles, impurities, and damage, its insulation performance may degrade, leading to faults such as breakdown or electric leakage, and in severe cases, even fires or electric shock accidents.

During the actual implementation, in the embodiment of the present disclosure, the potential defect existing in the outer sheath and the main insulation of the to-be-measured three-phase cable 205 may be diagnosed by using the voltage time-domain waveforms, thereby obtaining the final time-domain diagnosis result for the defect of the to-be-measured three-phase cable 205.

Optionally, in an embodiment of the present disclosure, the diagnosing, based on the voltage time-domain waveforms at the left end and the right end, the defect existing in the outer sheath and the main insulation of the to-be-measured three-phase cable 205, to obtain the final time-domain diagnosis result for the defect of the to-be-measured three-phase cable 205 includes: determining a phase where the defect is located based on the voltage time-domain waveforms; and determining a position where the defect is located and a direction of the defect based on the voltage time-domain waveforms. An absolute value of the position where the defect is located is:

$${L}_{f}^{kl} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

As a possible implementation manner, in the embodiment of the present disclosure, the final time-domain diagnosis result for the defect of the to-be-measured three-phase cable 205 determines, on the one hand, the phase where the defect is located, and on the other hand, the position where the defect is located and the direction of the defect.

In the embodiment of the present disclosure, in order to determine the phase where the defect is located, a phase where the potential defect in the to-be-measured three-phase cable 205 is located may be diagnosed comprehensively based on the voltage time-domain waveforms of the to-be-measured three-phase cable 205, and a health diagnosis result may be provided.

In the embodiment of the present disclosure, a time vector (T₁ᵢ, T₂ᵢ) corresponding to the injection mismatch point and the system mismatch point in the voltage time-domain waveforms may be extracted, where i=1, 2, 3, . . . , 6.

Then, in the embodiment of the present disclosure, a reflection threshold p may be set to extract a time corresponding to a pole with an absolute amplitude value greater than p in a Ui waveform, which is denoted as (t₁ᵢ, t₂ᵢ, . . . , tₙᵢ). n is the number of poles between (T₁ᵢ, T₂ᵢ) of the Ui waveform with p as the threshold.

Next, in the embodiment of the present disclosure, (t₁₁−T₁₁, t₂₁−T₁₁, . . . , t₍ₙ₁₎₁−T₁₁), (t₁₂−T₁₂, t₂₂−T₁₂, . . . , t₍ₙ₂₎₂−T₁₂), and (t₁₃−T₁₃, t₂₃−T₁₃, . . . , t₍ₙ₃₎₃−T₁₃) may be calculated.

Finally, in the embodiment of the present disclosure, a U1 waveform may be extracted, and compared with the extracted time vector. New time vectors are each compared one by one. If a time vector of U1 also exists in at least one other vector with epsilon as tolerance, the potential defect is considered to be of high severity and exists in a phase with a maximum extreme value at the time point. If the time vector of U1 does not exist in the other two vectors with epsilon as the tolerance, the potential defect is considered to be of low severity, and its propagation to other phases has attenuated to a negligible level. In addition, a phase corresponding to the defect is considered to be a phase represented by the U1 waveform. Determination logics for U2 and U3 are the same.

Further, in the embodiment of the present disclosure, the position where the defect is located and the direction of the defect may also be determined. That is, in the embodiment of the present disclosure, the direction of the defect may also be diagnosed, and the position of the defect may be determined.

In the embodiment of the present disclosure, voltage time-domain waveforms of another group of comparison phases may be selected based on a phase where the diagnosed defect is located.

Then, in the embodiment of the present disclosure, a time vector of the pole may be labeled, the time vectors in the waveforms are compared and analyzed one by one to determine whether the time vectors in the waveforms contain complementary time elements, and it is determined whether a sum of two complementary time elements is equal to T₂ᵢ−T₁ᵢ within a tolerance of psai. If the sum of the two complementary time elements is equal to T₂ᵢ−T₁ᵢ within the tolerance of psai, it can be determined that the tolerance is at a segment N, otherwise, it is determined that the tolerance is at a segment M.

Finally, in the embodiment of the present disclosure, a time tag of a fault point at the M-N segment of the cross-bonding box 206 is recorded, and then an absolute value of a position where the defect is located with the M-N segment of the cross-bonding box 206 as the zero point may be obtained. An absolute value of the position where the defect is located is:

$${L}_{f}^{kl} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, L₀ is a spacing between cross-bonding boxes, and tₖᵢ−T₁ᵢ is the time tag of the fault point at the M-N segment of the cross-bonding box.

In the embodiment of the present disclosure, an analysis for the M-N segment of the cross-bonding box 206 may be realized based on the voltage time-domain waveforms. Under a case of excluding a cross-bonding lead, a phase and a position where a potential defect in an M-N segment of the to-be-measured three-phase cable 205 is located, and a direction of the potential defect in the M-N segment of the to-be-measured three-phase cable 205 may be diagnosed with higher accuracy. In addition, during the actual implementation, an analysis process of the N-O segment of the cross-bonding box 206 is similar to that of the M-N segment of the cross-bonding box 206, with only differences in selection of data groups, and details are omitted herein.

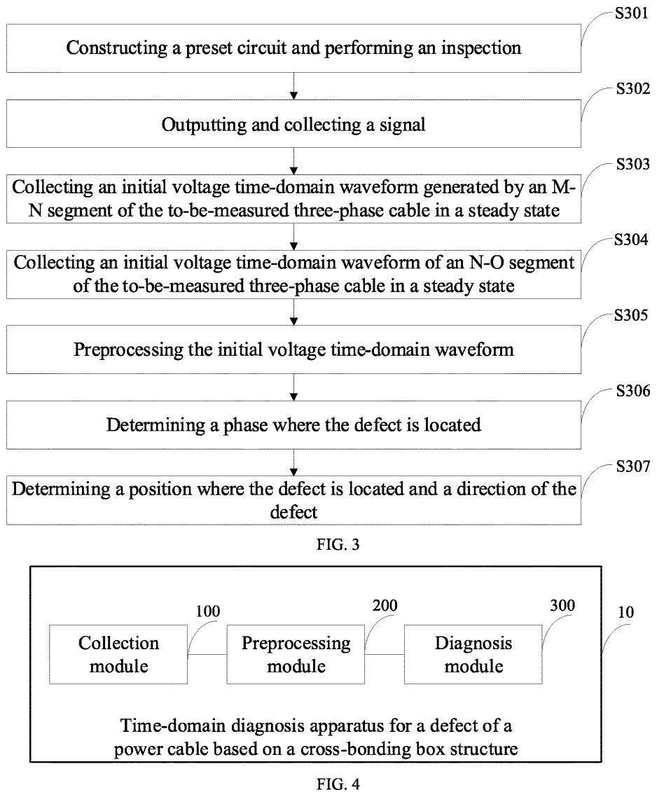

Referring to FIG. 3, a working principle of the time-domain diagnosis method for the defect of the power cable based on the cross-bonding box structure provided according to the embodiments of the present disclosure will be described in detail through a specific embodiment.

FIG. 3 is a schematic block diagram of a working principle of a time-domain diagnosis method for a defect of a power cable based on a cross-bonding box structure provided according to an embodiment of the present disclosure.

In step S301, a preset circuit is constructed, and an inspection is performed. That is, in the embodiment of the present disclosure, the preset circuit may be constructed in a manner shown in FIG. 1. After the preset circuit is constructed, it is inspected whether the connection is electrically reliable.

In step S302, a signal is outputted and collected. That is, in the embodiment of the present disclosure, the waveform generator may output a broadband signal with a certain repetition frequency, and the signal collection apparatus 202 may collect a port signal U0.

In step S303, an initial voltage time-domain waveform generated by an M-N segment of the to-be-measured three-phase cable 205 in a steady state is collected. In the embodiment of the present disclosure, an injection pole at an end of the second cable segment 2042 may be connected to a/a/b of the M-N segment of the cross-bonding box 206, and a return pole at the end of the second cable segment 2042 may be connected to c/b/c of the M-N segment of the cross-bonding box 206. Previous settings of the waveform generator and the signal collection apparatus 202 are maintained, port signals U1, U2, and U3 within a single cycle in the steady state under such a case are collected.

In step S304, an initial voltage time-domain waveform generated by an N-O segment of the to-be-measured three-phase cable 205 in a steady state is collected. In the embodiment of the present disclosure, the injection pole at the end of the second cable segment 2042 may be connected to a/a/b of the N-O segment of the cross-bonding box 206, and the return pole at the end of the second cable segment 2042 may be connected to c/b/c of the N-O segment of the cross-bonding box 206. Previous settings of the waveform generator and the signal collection apparatus 202 are maintained, port signals U4, U5, and U6 within a single cycle in the steady state under such a case are collected.

In step S305, the initial voltage time-domain waveforms are preprocessed. That is, in the embodiment of the present disclosure, based on the U1 to U6, the discrete wavelet transform may be performed, and the hard threshold method may be selected to filter the collected initial voltage time-domain waveforms. The wavelet transform coefficient ψ_{a,b}(t) is expressed as:

$${ψ}_{a , b} ( t ) = \frac{1}{\sqrt{{2}^{a}}} ψ ( \frac{t - b}{{2}^{a}} ) ,$$

in which ψ is a wavelet basis function.

Further, in the embodiment of the present disclosure, a 5-layer decomposition coefficient and the hard threshold method may be selected to filter out the noise. The hard threshold method is:

$${k}_{δ} = \{ \begin{matrix}{ψ}_{a , b} ( t ) & if \vert {ψ}_{a , b} ( t ) \vert > δ \\ & 0\end{matrix} ,$$

in which k_{δ} is a wavelet transform coefficient processed by the hard threshold method, ψ_{a,b}(t) is a wavelet transform coefficient, and δ is a set hard threshold.

The expression of the hard threshold is:

$$δ = \frac{m}{0.6745} \cdot \sqrt{2 log n} ,$$

in which m is a median value of a signal decomposition layer, and n is a length of the signal decomposition layer.

Further, in the embodiment of the present disclosure, an inverse wavelet transform is performed on the filtered result to obtain the voltage time-domain waveforms after the noise filtration.

In step S306, the phase where the defect is located is determined. That is, in the embodiment of the present disclosure, in order to determine the phase where the defect is located, a phase where the potential defect in the to-be-measured three-phase cable 205 is located may be diagnosed comprehensively based on the voltage time-domain waveforms of the to-be-measured three-phase cable 205, and a health diagnosis result may be provided.

In the embodiment of the present disclosure, a time vector (T₁ᵢ, T₂ᵢ) corresponding to the injection mismatch point and the system mismatch point in the voltage time-domain waveforms may be extracted, where i=1, 2, 3, . . . , 6.

Then, in the embodiment of the present disclosure, a reflection threshold p may be set to extract a time corresponding to a pole with an absolute amplitude value greater than p in an Ui waveform, which is denoted as (t₁ᵢ, t₂ᵢ, . . . , tₙᵢ). n is the number of poles between (T₁ᵢ, T₂ᵢ) of the Ui waveform with p as the threshold.

Next, in the embodiment of the present disclosure, (t₁₁−T₁₁, t₂₁−T₁₁, . . . , t₍ₙ₁₎₁−T₁₁), (t₁₂−T₁₂, t₂₂−T₁₂, . . . , t₍ₙ₂₎₂−T₁₂), and (t₁₃−T₁₃, t₂₃−T₁₃, . . . , t₍ₙ₃₎₃−T₁₃) may be calculated.

Finally, in the embodiment of the present disclosure, a U1 waveform may be extracted, and compared with the extracted time vector. New time vectors are each compared one by one. If a time vector of U1 also exists in at least one other vector with epsilon as tolerance, the potential defect is considered to be of high severity and exists in a phase with a maximum extreme value at the time point. If the time vector of U1 does not exist in the other two vectors with epsilon as the tolerance, the potential defect is considered to be of low severity, and its propagation to other phases has attenuated to a negligible level. In addition, a phase corresponding to the defect is considered to be a phase represented by the U1 waveform. Determination logics for U2 and U3 are the same.

In step S307, the position where the defect is located and the direction of the defect are determined. That is, in the embodiment of the present disclosure, the position where the defect is located and the direction of the defect may also be determined. It can be understood that, in the embodiment of the present disclosure, the direction of the defect may be diagnosed, and the position of the defect may be determined.

In the embodiment of the present disclosure, voltage time-domain waveforms of another group of comparison phases may be selected based on a phase where the diagnosed defect is located.

Then, in the embodiment of the present disclosure, a time vector of the pole may be labeled, the time vectors in the waveform are compared and analyzed one by one to determine whether the time vectors in the waveform contain complementary time elements, and it is determined whether a sum of two complementary time elements is equal to T₂ᵢ−T₁ᵢ within a tolerance of psai. If the sum of the two complementary time elements is equal to T₂ᵢ−T₁ᵢ within the tolerance of psai, it can be determined that the tolerance is at a segment N, otherwise, it is determined that the tolerance is at a segment M.

Finally, in the embodiment of the present disclosure, a time tag of a fault point at the M-N segment of the cross-bonding box 206 is recorded, and then an absolute value of a position where the defect is located with the M-N segment of the cross-bonding box 206 as the zero point may be obtained. An absolute value of the position where the defect is located is:

$${L}_{f}^{ki} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, L₀ is a spacing between cross-bonding boxes, and tₖᵢ−T₁ᵢ is the time tag of the fault point at the M-N segment of the cross-bonding box.

In the embodiment of the present disclosure, an analysis for the M-N segment of the cross-bonding box 206 may be realized based on the voltage time-domain waveform. Under a case of excluding a cross-bonding lead, a phase and a position where a potential defect in an M-N segment of the to-be-measured three-phase cable 205 is located, and a direction of the potential defect in the M-N segment of the to-be-measured three-phase cable 205 may be diagnosed with higher accuracy. In addition, during the actual implementation, an analysis process of the N-O segment of the cross-bonding box 206 is similar to that of the M-N segment of the cross-bonding box 206, with only differences in selection of data groups, and details are omitted herein.

In addition, in the embodiment of the present disclosure, without disconnecting the to-be-measured three-phase cable 205, a signal is injected only into two adjacent cross-bonding boxes 206, which can realize identification and positioning of the potential defect in the outer sheath and the main insulation of the to-be-measured three-phase cable 205, overcome drawbacks of an active injection method in the related art, such as system disconnection and difficulty in online monitoring, and have broad application prospects in positioning, identification, and diagnosis of the defect in the to-be-measured three-phase cable 205.

With the time-domain diagnosis method for the defects of the power cable based on the cross-bonding box structure provided according to the embodiments of the present disclosure, a broadband signal may be injected through a wiring terminal of a cross-bonding box for cross-connection of three-phase shielding layers, and a time-domain diagnosis result of a defect existing in an outer sheath and main insulation of a three-phase cable may be diagnosed based on voltage time-domain waveforms in a steady state generated based on the broadband signal, which realizes simultaneous diagnosis of potential defects in the outer sheath and the main insulation of the three-phase cable and provides diagnostic positioning without disconnecting an electrical connection of a three-phase cable system, thereby realizing evaluation of a health state of the three-phase cable system, reducing the demand and cost of the on-site device, improving the practicality, and further making the online monitoring possible. Therefore, the technical problems in the related art, such as the disconnection of the exposed core wires of the cable in the power cable system, the damage to the complete topological structure of the power cable system, the difficulty in achieving the online monitoring, the increased demand for the on-site device, the relatively high complexity and cost of the routing inspection, and the low practicality, are solved.

Next, a time-domain diagnosis apparatus for the defect of the power cable based on the cross-bonding box structure according to the embodiment of the present disclosure will be described with reference to the accompanying drawings.

FIG. 4 is a schematic block diagram of a time-domain diagnosis apparatus for a defect of a power cable based on a cross-bonding box structure provided according to an embodiment of the present disclosure.

As shown in FIG. 4, the time-domain diagnosis apparatus 10 for the defect of the power cable based on the cross-bonding box structure includes: a collection module 100, a preprocessing module 200, and a diagnosis module 300.

In an embodiment, the collection module 100 is configured to inject a broadband signal through a wiring terminal of a cross-bonding box for cross-connection of three-phase shielding layers, to collect an initial voltage time-domain waveform of a to-be-measured three-phase cable in a steady state generated based on the broadband signal.

The preprocessing module 200 is configured to preprocess the initial voltage time-domain waveforms at the same end, to obtain preprocessed voltage time-domain waveforms at a left end and a right end of the cross-bonding box.

The diagnosis module 300 is configured to diagnose, based on the voltage time-domain waveforms at the left end and the right end, a defect existing in an outer sheath and main insulation of the to-be-measured three-phase cable, to obtain a final time-domain diagnosis result for the defect of the to-be-measured three-phase cable.

Optionally, in an embodiment of the present disclosure, the preprocessing module 200 includes a generation unit.

The generation unit is configured to perform a discrete wavelet transform on the initial voltage time-domain waveforms, and select a hard threshold method to filter the initial voltage time-domain waveforms after the discrete wavelet transform to obtain the voltage time-domain waveforms.

Optionally, in an embodiment of the present disclosure, the hard threshold method is:

$${k}_{δ} = \{ \begin{matrix}{ψ}_{a , b} ( t ) & if \vert {ψ}_{a , b} ( t ) \vert > δ \\ & 0\end{matrix} ,$$

in which k_{δ} is a wavelet transform coefficient processed by the hard threshold method, ψ_{a,b}(t) is a wavelet transform coefficient, and δ is a set hard threshold.

The expression of the hard threshold is:

$$δ = \frac{m}{0.6745} \cdot \sqrt{2 log n} ,$$

in which m is a median value of a signal decomposition layer, and n is a length of the signal decomposition layer.

Optionally, in an embodiment of the present disclosure, the diagnosis module 300 includes: a first determination unit and a second determination unit.

The first determination unit is configured to determine a phase where the defect is located based on the voltage time-domain waveform.

The second determination unit is configured to determine a position where the defect is located and a direction of the defect based on the voltage time-domain waveform.

Optionally, in an embodiment of the present disclosure, an absolute value of the position where the defect is located is:

$${L}_{f}^{ki} = \frac{{t}_{ki} - {T}_{1 i}}{{T}_{2 i} - {T}_{1 i}} \cdot {L}_{0} ,$$

in which tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

It should be noted that the above explanation of the embodiments of the time-domain diagnosis method for the defect of the power cable based on the cross-bonding box structure is also applicable to the time-domain diagnosis apparatus for the defect of the power cable based on the cross-bonding box structure according to this embodiment, and thus details thereof will be omitted here.

With the time-domain diagnosis apparatus for the defect of the power cable based on the cross-bonding box structure provided according to the embodiments of the present disclosure, a broadband signal may be injected through a wiring terminal of a cross-bonding box for cross-connection of three-phase shielding layers, and a time-domain diagnosis result of a defect existing in an outer sheath and main insulation of a three-phase cable may be diagnosed based on voltage time-domain waveforms in a steady state generated based on the broadband signal, which realizes simultaneous diagnosis of potential defects in the outer sheath and the main insulation of the three-phase cable and provides diagnostic positioning without disconnecting an electrical connection of a three-phase cable system, thereby realizing evaluation of a health state of the three-phase cable system, reducing the demand and cost of the on-site device, improving the practicality, and further making the online monitoring possible. Therefore, the technical problems in the related art, such as the disconnection of the exposed core wires of the cable in the power cable system, the damage to the complete topological structure of the power cable system, the difficulty in achieving the online monitoring, the increased demand for the on-site device, the relatively high complexity and cost of the routing inspection, and the low practicality, are solved.

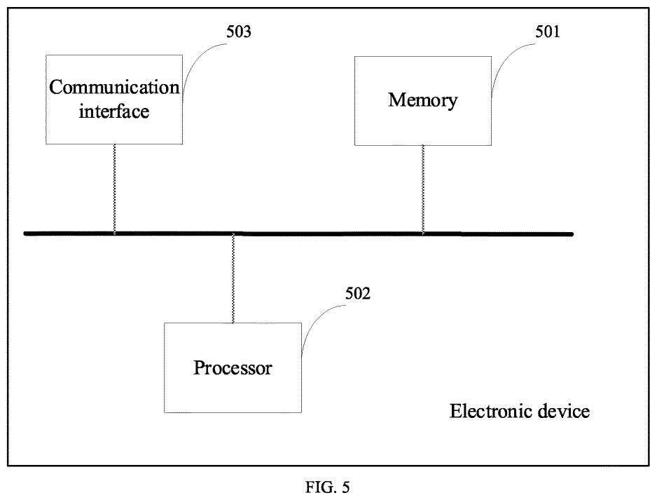

FIG. 5 is a schematic structural diagram of an electronic device provided according to an embodiment of the present disclosure. The electronic device may include a memory 501, a processor 502, and a computer program stored on the memory 501 and executable on the processor 502.

The processor 502, when executing the computer program, implements the time-domain diagnosis method for the defect of the power cable based on the cross-bonding box structure provided in the above embodiments.

The electronic device further includes: a communication interface 503 configured to communicate between the memory 501 and the processor 502.

The memory 501 is configured to store a computer program executable on the processor 502. The memory 501 may include a high-speed Random Access Memory (RAM), and may also include a non-volatile memory, such as at least one disk memory.

When the memory 501, the processor 502, and the communication interface 503 are implemented independently, the communication interface 503, the memory 501, and the processor 502 may be interconnected and communicate with each other via a bus. The bus may be an Industry Standard Architecture (ISA) bus, a Peripheral Component Interconnect (PCI) bus, or an Extended Industry Standard Architecture (EISA) bus. The buses may be divided into an address bus, a data bus, a control bus, etc. For the convenience of description, only one thick line is used in FIG. 5, but it does not mean that there is only one bus or one type of bus.

Optionally, in a specific implementation, when the memory 501, the processor 502, and the communication interface 503 are integrated on a single chip for an implementation, the memory 501, the processor 502, and the communication interface 503 may communicate with each other through an internal interface.

The processor 502 may be a Central Processing Unit (CPU), or an Application Specific Integrated Circuit (ASIC), or one or more integrated circuits configured to implement an embodiment of the present disclosure.

The embodiments of the present disclosure further provide a computer-readable storage medium. The computer-readable storage medium has a computer program stored thereon. The computer program, when executed by a processor, implements the time-domain diagnosis method for the defect of the power cable based on the cross-bonding box structure as described above.

The embodiments of the present disclosure further provide a computer program product, including a computer program. The computer program, when executed by the processor, implements the time-domain diagnosis method for the defect of the power cable based on the cross-bonding box structure as described above.

In the description of this specification, descriptions with reference to the terms “an embodiment”, “some embodiments”, “examples”, “specific examples”, or “some examples” etc., mean that specific features, structure, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or N embodiments or examples in a suitable manner. In addition, those skilled in the art can combine the different embodiments or examples and the features of the different embodiments or examples described in this specification without contradicting each other.

In addition, the terms “first” and “second” are only used for descriptive purposes, and cannot be understood as indicating or implying relative importance or implicitly indicating the number of indicated technical features. Therefore, the features associated with “first” and “second” may explicitly or implicitly include at least one of the features. In the description of the present disclosure, “N” means at least two, such as two, three, etc., unless otherwise specifically defined.

Any process or method described in a flowchart or described herein in other ways may be understood to include one or N modules, segments, or portions of codes of executable instructions for achieving specific logical functions or steps in the process. The scope of a preferred embodiment of the present disclosure includes other implementations. A function may be performed not in a sequence shown or discussed, including a substantially simultaneous manner or a reverse sequence based on the function involved, which should be understood by those skilled in the art to which the embodiments of the present disclosure belong.

The logic and/or step described in other manners herein or shown in the flowchart, for example, a particular sequence table of executable instructions for realizing the logical function, may be specifically realized in any computer readable medium to be used by the instruction execution system, device or equipment (such as the system based on computers, the system including processors or other systems capable of obtaining the instructions from the instruction execution system, device and equipment and executing the instructions), or to be used in combination with the instruction execution system, device and equipment. As to the specification, “the computer readable medium” may be any device adaptive for including, storing, communicating, propagating or transferring programs to be used by or in combination with the instruction execution system, device or equipment. More specific examples of the computer readable medium include but are not limited to: an electronic connection (an electronic device) with one or N wires, a portable computer disk case (a magnetic device), a random access memory (RAM), a read only memory (ROM), an erasable programmable read-only memory (EPROM or a flash memory), an optical fiber device and a portable compact disk read-only memory (CDROM). In addition, the computer readable medium may even be a paper or other appropriate medium capable of being printed with programs thereon, this is because, for example, the paper or other appropriate medium may be optically scanned and then edited, decrypted or processed with other appropriate methods when necessary to obtain the programs in an electric manner, and then the programs may be stored in the computer memory.

It should be understood that each part of the present disclosure may be realized by the hardware, software, firmware or their combination. In the above embodiments, N steps or methods may be realized by the software or firmware stored in the memory and executed by the appropriate instruction execution system. For example, if it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a programmable gate array (PGA), a field programmable gate array (FPGA), etc.

Those skilled in the art shall understand that all or parts of the steps in the above method of the embodiments of the present disclosure may be achieved by instructing the related hardware by programs. The programs may be stored in a computer readable storage medium, and the programs include one or a combination of the steps in the method embodiments of the present disclosure when run on a computer.

In addition, each function cell of the embodiments of the present disclosure may be integrated in a processing module, or these cells may exist separately physically, or two or more cells are integrated in a processing module. The integrated module may be realized in a form of hardware or in a form of software function modules. When the integrated module is realized in a form of software function module and is sold or used as a standalone product, the integrated module may be stored in a computer readable storage medium.

The storage medium mentioned above may be read-only memories, magnetic disks, CD, etc. Although the embodiments of the present disclosure have been shown and described, it would be appreciated by those skilled in the art that the above embodiments are illustrative and cannot be construed to limitation on the present disclosure, and changes, alternatives, modifications, and variations can be made in the embodiments without departing from scope of the present disclosure.

What is claimed is:

1. A time-domain diagnosis method for a defect of a power cable based on a cross-bonding box structure, wherein the method comprises:
injecting a broadband signal through a wiring terminal of a cross-bonding box for cross-connection of three-phase shielding layers, to collect an initial voltage time-domain waveform of a to-be-measured three-phase cable in a steady state generated based on the broadband signal;
preprocessing the initial voltage time-domain waveforms at the same end, to obtain preprocessed voltage time-domain waveforms at a left end and a right end of the cross-bonding box; and
diagnosing, based on the voltage time-domain waveforms at the left end and the right end, the defect existing in an outer sheath and main insulation of the to-be-measured three-phase cable, to obtain a final time-domain diagnosis result for the defect of the to-be-measured three-phase cable.

2. The method according to claim 1, wherein said preprocessing the initial voltage time-domain waveforms at the same end, to obtain the preprocessed voltage time-domain waveforms at the left end and the right end of the cross-bonding box comprises:
performing a discrete wavelet transform on the initial voltage time-domain waveforms, and selecting a hard threshold method to filter the initial voltage time-domain waveforms after the discrete wavelet transform to obtain the voltage time-domain waveforms.

3. The method according to claim 2, wherein the hard threshold method is:
$${k}_{δ} = \{ \begin{matrix}{ψ}_{a , b} ( t ) & if \vert {ψ}_{a , b} ( t ) \vert > δ \\ & 0\end{matrix} ,$$
wherein k_{δ} is a wavelet transform coefficient processed by the hard threshold method, ψ_{a,b}(t) is a wavelet transform coefficient, and δ is a set hard threshold,
wherein an expression of the hard threshold is:
$$δ = \frac{m}{0.6745} \cdot \sqrt{2 log n} ,$$
wherein m is a median value of a signal decomposition layer, and n is a length of the signal decomposition layer.

4. The method according to claim 1, wherein said diagnosing, based on the voltage time-domain waveforms at the left end and the right end, the defect existing in the outer sheath and the main insulation of the to-be-measured three-phase cable, to obtain the final time-domain diagnosis result for the defect of the to-be-measured three-phase cable comprises:
determining a phase where the defect is located based on the voltage time-domain waveforms; and
determining a position where the defect is located and a direction of the defect based on the voltage time-domain waveforms.

5. The method according to claim 4, wherein an absolute value of the position where the defect is located is:
$${L}_{f}^{ki} = \frac{{t}_{ki} - {T}_{1 i}}{{T}_{2 i} - {T}_{1 i}} \cdot {L}_{0} ,$$
wherein tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

6. An electronic device, comprising:
a memory;
a processor; and
a computer program stored on the memory and executable on the processor, wherein the processor executes the program to implement a time-domain diagnosis method for a defect of a power cable based on the cross-bonding box structure,
wherein the method comprises:
injecting a broadband signal through a wiring terminal of a cross-bonding box for cross-connection of three-phase shielding layers, to collect an initial voltage time-domain waveform of a to-be-measured three-phase cable in a steady state generated based on the broadband signal;
preprocessing the initial voltage time-domain waveforms at the same end, to obtain preprocessed voltage time-domain waveforms at a left end and a right end of the cross-bonding box; and
diagnosing, based on the voltage time-domain waveforms at the left end and the right end, the defect existing in an outer sheath and main insulation of the to-be-measured three-phase cable, to obtain a final time-domain diagnosis result for the defect of the to-be-measured three-phase cable.

7. The electronic device according to claim 6, wherein said preprocessing the initial voltage time-domain waveforms at the same end, to obtain the preprocessed voltage time-domain waveforms at the left end and the right end of the cross-bonding box comprises:
performing a discrete wavelet transform on the initial voltage time-domain waveforms, and selecting a hard threshold method to filter the initial voltage time-domain waveforms after the discrete wavelet transform to obtain the voltage time-domain waveforms.

8. The electronic device according to claim 7, wherein the hard threshold method is:
$${k}_{δ} = \{ \begin{matrix}{ψ}_{a , b} ( t ) & if \vert {ψ}_{a , b} ( t ) \vert > δ \\ & 0\end{matrix} ,$$
wherein k_{δ} is a wavelet transform coefficient processed by the hard threshold method, ψ_{a,b}(t) is a wavelet transform coefficient, and δ is a set hard threshold,
wherein an expression of the hard threshold is:
$$δ = \frac{m}{0.6745} \cdot \sqrt{2 log n} ,$$
wherein m is a median value of a signal decomposition layer, and n is a length of the signal decomposition layer.

9. The electronic device according to claim 6, wherein said diagnosing, based on the voltage time-domain waveforms at the left end and the right end, the defect existing in the outer sheath and the main insulation of the to-be-measured three-phase cable, to obtain the final time-domain diagnosis result for the defect of the to-be-measured three-phase cable comprises:
determining a phase where the defect is located based on the voltage time-domain waveforms; and
determining a position where the defect is located and a direction of the defect based on the voltage time-domain waveforms.

10. The electronic device according to claim 9, wherein an absolute value of the position where the defect is located is:
$${L}_{f}^{ki} = \frac{{t}_{ki} - {T}_{1 i}}{{T}_{2 i} - {T}_{1 i}} \cdot {L}_{0} ,$$
wherein tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

11. A non-transitory computer-readable storage medium, having a computer program stored thereon, wherein the program, when executed by a processor, is configured to implement a time-domain diagnosis method for a defect of a power cable based on a cross-bonding box structure,
wherein the method comprises:
injecting a broadband signal through a wiring terminal of a cross-bonding box for cross-connection of three-phase shielding layers, to collect an initial voltage time-domain waveform of a to-be-measured three-phase cable in a steady state generated based on the broadband signal;
preprocessing the initial voltage time-domain waveforms at the same end, to obtain preprocessed voltage time-domain waveforms at a left end and a right end of the cross-bonding box; and
diagnosing, based on the voltage time-domain waveforms at the left end and the right end, the defect existing in an outer sheath and main insulation of the to-be-measured three-phase cable, to obtain a final time-domain diagnosis result for the defect of the to-be-measured three-phase cable.

12. The non-transitory computer-readable storage medium according to claim 11, wherein said preprocessing the initial voltage time-domain waveforms at the same end, to obtain the preprocessed voltage time-domain waveforms at the left end and the right end of the cross-bonding box comprises:
performing a discrete wavelet transform on the initial voltage time-domain waveforms, and selecting a hard threshold method to filter the initial voltage time-domain waveforms after the discrete wavelet transform to obtain the voltage time-domain waveforms.

13. The non-transitory computer-readable storage medium according to claim 12, wherein the hard threshold method is:
$${k}_{δ} = \{ \begin{matrix}{ψ}_{a , b} ( t ) & if \vert {ψ}_{a , b} ( t ) \vert > δ \\ & 0\end{matrix} ,$$
wherein k_{δ} is a wavelet transform coefficient processed by the hard threshold method, ψ_{a,b}(t) is a wavelet transform coefficient, and δ is a set hard threshold,
wherein an expression of the hard threshold is:
$$δ = \frac{m}{0.6745} \cdot \sqrt{2 log n} ,$$
wherein m is a median value of a signal decomposition layer, and n is a length of the signal decomposition layer.

14. The non-transitory computer-readable storage medium according to claim 11, wherein said diagnosing, based on the voltage time-domain waveforms at the left end and the right end, the defect existing in the outer sheath and the main insulation of the to-be-measured three-phase cable, to obtain the final time-domain diagnosis result for the defect of the to-be-measured three-phase cable comprises:
determining a phase where the defect is located based on the voltage time-domain waveforms; and
determining a position where the defect is located and a direction of the defect based on the voltage time-domain waveforms.

15. The non-transitory computer-readable storage medium according to claim 14, wherein an absolute value of the position where the defect is located is:
$${L}_{f}^{ki} = \frac{{t}_{ki} - {T}_{1 i}}{{T}_{2 i} - {T}_{1 i}} \cdot {L}_{0} ,$$
wherein tₖᵢ is a time corresponding to a k-th pole with an absolute amplitude value greater than p in an i-th test voltage waveform, T₁ᵢ is a time corresponding to an injection mismatch point in i-th test voltage data, T₂ᵢ is a time corresponding to a system mismatch point in the i-th test voltage data, k is a label of the pole, i is a label of a to-be-measured voltage, and L₀ is a spacing between cross-bonding boxes.

16. A computer program product, comprising a computer program, wherein the computer program, when executed, is configured to implement the time-domain diagnosis method for the defect of the power cable based on the cross-bonding box structure according to claim 1.
